(19) United States
(12) Patent Application Publication
(10) Pub. No.: US 2026/0344418 A1
(43) Pub. Date: Oct. 29, 2026

(54) METHOD OF SEMICONDUCTOR MANUFACTURING AND CORRESPONDING SEMICONDUCTOR DEVICE

(71) Applicant: STMicroelectronics International N.V., Geneva (CH)

(72) Inventor: Dario VITELLO, Merate (LC) (IT)

(73) Assignee: STMicroelectronics International N.V., Geneva (CH)

(21) Appl. No.: 19/660,768

(22) Filed: Apr. 28, 2026

(30) Foreign Application Priority Data
Apr. 29, 2025 (IT) 102025000009438

(51) Int. Cl. H10W 40/22; H10W 40/00; H10W 74/01; H10W 74/10

(52) U.S. Cl. CPC H10W 40/22; H10W 40/03; H10W 74/01; H10W 74/111

(57) ABSTRACT

An encapsulation of electrically insulating encapsulation material, having opposite first and second surfaces, embeds at least one semiconductor die having an active surface at the first surface of the encapsulation and a back surface opposite said active surface covered by electrically insulating encapsulation material. Vias extending from the second surface towards the back surface of the at least one semiconductor die are formed by laser beam energy. Thermally conductive material grown at the second surface of encapsulation produces a heat dissipation formation for the at least one semiconductor die. The heat dissipation formation includes a thermally conductive layer on the second surface of the encapsulation thermally coupled to the at least one semiconductor die via thermally conductive material grown at the vias formed in the second surface of the encapsulation.

### PRIORITY CLAIM

This application claims the priority benefit of Italian Application for Patent No. 102025000009438 filed on Apr. 29, 2025, the content of which is hereby incorporated by reference in its entirety to the maximum extent allowable by law.

### TECHNICAL FIELD

The description relates to semiconductor devices.

One or more embodiments can be applied to manufacturing processes of (integrated circuit (IC)) semiconductor devices.

### BACKGROUND

Power semiconductor devices may generate a relatively high amount of heat during normal operation. In order to facilitate dissipation of heat, power devices may be provided with a package having a heatsink exposed at a surface thereof that facilitates heat dissipation.

Devices processed via so-called panel level packaging (PLP) may also be provided with such a heatsink. In such processes, an electrically insulating molding compound is molded onto a plurality of semiconductor dice to embed the dice in a panel. Subsequently, the molding compound is partially removed via a grinding/milling apparatus in order to expose the back surface of the dice.

A thermally conductive layer is then formed in contact (and in a heat transfer relationship) with the exposed back surface of the dice.

It has been observed that such a grinding or milling step can damage the dice; in fact, especially in relatively large panels, it is difficult to control the mechanical milling step, which may undesirably result in damage of the dice in the panel, causing considerable yield loss due to formations of cracks in the dice.

Reference is made to United States Patent Application Publication Nos. 2022/0093515 A1, 2014/0319678 A1, and 2020/0343184 A1, as well as United States Patent Nos. 11,869,829 B2 and 8,034,643 B2, all of which are incorporated herein by reference, as providing background information in the related technological area.

There is a need in the art to overcome the drawbacks discussed in the foregoing.

### SUMMARY

One or more embodiments relate to a method.

One or more embodiments also relate to a corresponding semiconductor device.

Solutions as described herein involve providing a device where heat generated by a semiconductor die in the device may be dissipated via a heat dissipation formation or heatsink.

According to solutions as described herein the heatsink may comprise a thermally conductive layer exposed at a surface of the encapsulation of the device and thermally coupled to the semiconductor die via thermally conductive vias through the encapsulation.

In solutions as described herein, the thermally conductive vias are formed via laser ablation of encapsulation material covering a back surface of the semiconductor die, followed by growth of thermally conductive material.

Solutions as described herein may advantageously be applied to panel level packaging processes of semiconductor devices.

### BRIEF DESCRIPTION OF THE DRAWINGS

One or more embodiments will now be described, by way of example only, with reference to the annexed figures, wherein:

FIGS. 1A-1D are cross-sectional views illustrative of a sequence of processing steps in manufacturing semiconductor devices;

FIGS. 2A-2H are cross-sectional views illustrative of a sequence of processing steps; and

FIG. 3 is a cross-sectional view illustrative of further embodiments.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

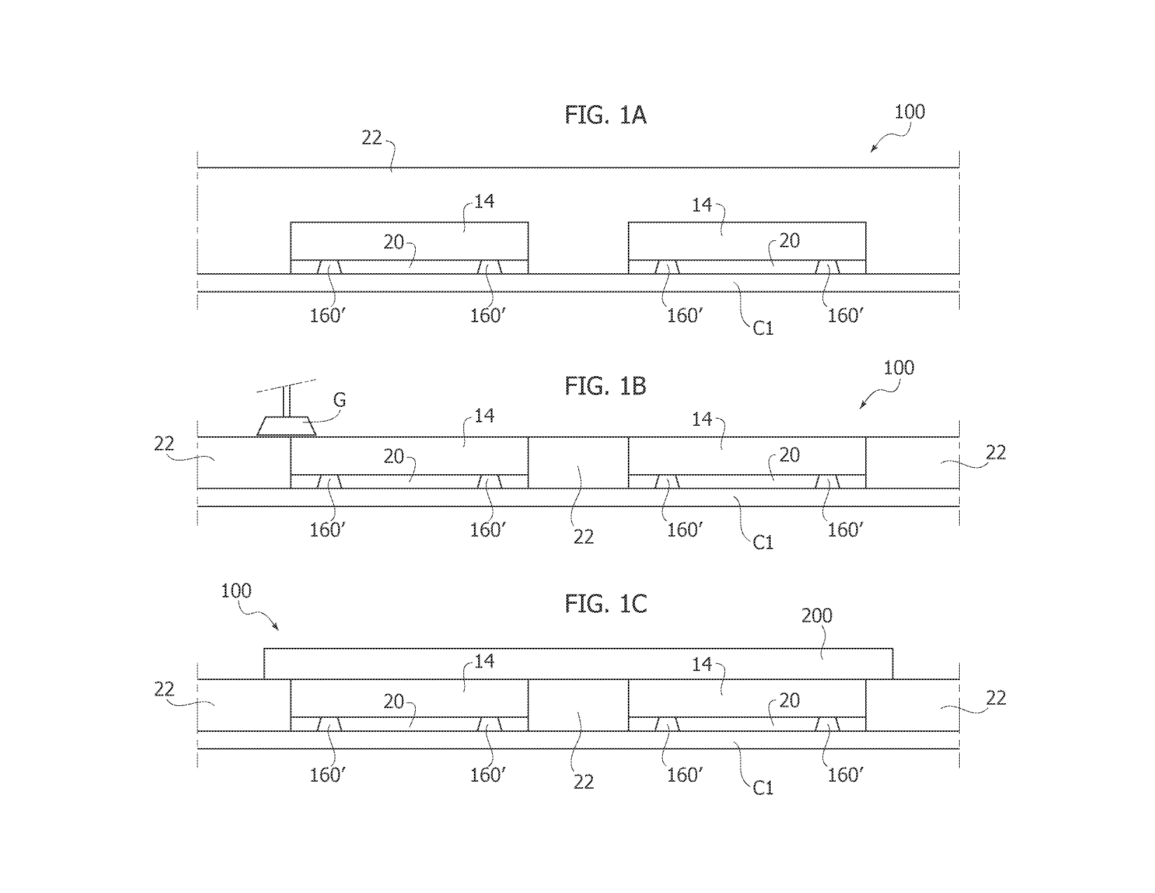

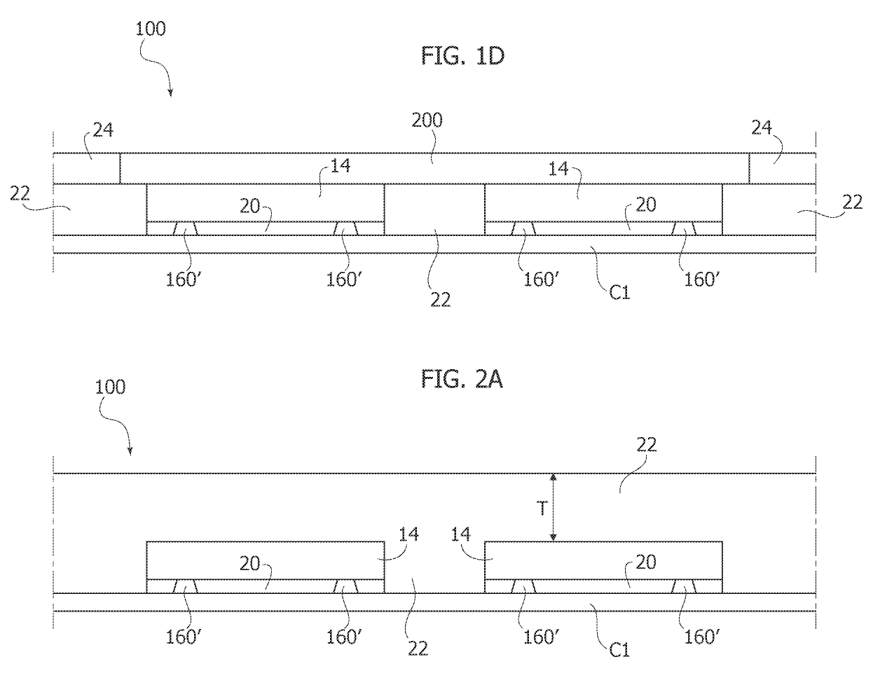

FIGS. 1A-1D are cross-sectional views illustrative of processing steps in manufacturing semiconductor devices via panel or wafer level packaging. Hereinafter, reference will be made to a panel being otherwise understood that the sequences of processing steps as described herein may be applied to both wafer level and/or panel level processing, irrespective of the particular shape and/or size of the wafer or panel.

FIG. 1A is illustrative of a panel 100 arranged on a temporary (and possibly sacrificial) carrier C1. The panel 100 illustrated in FIG. 1A comprises a plurality of integrated circuit (IC) semiconductor dice or chips 14 (the terms chip/chips and die/dice are herein regarded as synonymous) embedded in an electrically insulating encapsulation 22 of molding compound (an epoxy resin, for instance).

Providing a panel 100 as illustrate in FIG. 1A may involve: providing a semiconductor (Si, SiC, GaN, for instance) wafer having embedded therein (in any way known in the art) a plurality of integrated circuits, ICs, (not visible in the figures for simplicity); laminating an electrically insulating build-up film 20 (also referred to as mold film), such as an Ajinomoto Build-Up Film, at a surface of the semiconductor wafer (the active surface); opening (via laser ablation, for instance) vias 160’ towards the active surface of the semiconductor dice 14 through the build-up film 20 to uncover corresponding die bonding pads (that is, electrical contacts, not visible in the figures for scale reasons) at the active surface of the semiconductor dice 14; singulating the semiconductor wafer into a plurality of individual (singulated) semiconductor dice 14, each semiconductor die 14 comprising at least one integrated circuit and a portion of the build-up film 20 laminated at the active surface thereof; arranging (for example through a pick and place operation) the plurality of individual (singulated) semiconductor dice 14, spaced apart from each other, on a temporary carrier C1, with the active surface of the semiconductor dice 14 facing the temporary carrier C1; and molding an electrically insulating molding material 22 (an epoxy resin, for instance) onto the plurality of individual semiconductor dice 14 arranged on the temporary carrier.

As illustrated in FIG. 1A, each semiconductor die 14 has a portion of the build-up film 20 (laminated prior to the singulation step, for instance) provided at the active surface of the semiconductor die 14, with vias 160’ opened through the build-up film 20 towards the die bonding pads of the semiconductor die 14. The reference 160’ with an accent ’ designation is used to highlight the fact that an opening for the via is present and that proper, electrically conductive, vias will be formed within the openings in a subsequent processing step. The semiconductor dice 14 are arranged with the active surface at the bottom surface of the panel 100, facing the first carrier C1.

As illustrated in FIG. 1B, the electrically insulating molding material 22 is partially removed (via a grinding apparatus G, for instance) in order to expose a back surface of the semiconductor dice 14 (that is, the surface opposite the active surface) at a (top) surface of the panel 100.

Subsequently, with reference to FIGS. 1C and 1D, a thermally conductive layer 200 is formed at the back surface of the semiconductor dice 14 exposed at the top/front surface of the panel 100. The thermally conductive layer 200 may be formed via electrolytic plating of electrically (and thermally) conductive material (a metallic material such as copper, for instance). As illustrated, the thermally conductive layer 200 may be formed onto the back surface of the semiconductor dice 14. Contact between the thermally conductive layer 200 and the back surface of the semiconductor dice 14 facilitates heat transfer from the semiconductor dice 14 to the thermally conductive layer 200.

As illustrated in FIG. 1D, a (further) molding step is performed in order to encapsulate the thermally conductive layer 200. The further (electrically insulating) molding material 24 leaves exposed a top/front surface of the thermally conductive layer 200, thus facilitating dissipation of heat to the outside of the device.

Further processing of a panel 100 as illustrated in FIG. 1D may comprise: forming a redistribution layer at the active surface of the panel 100 (the bottom surface of the panel 100 illustrated in FIG. 1D); forming studs or pads onto the redistribution layer, with the studs or pads electrically coupled to semiconductor dice 14 in the plurality of semiconductor dice 14 embedded in the panel 100 via the redistribution layer; and singulating the processed panel 100 into a plurality of panel portions, each panel portion providing an individual (finished) device.

Devices processed as described in the foregoing are thus provided with a thermally conductive layer 200 exposed at a surface of the package that facilitates dissipation of heat. Such a thermally conductive layer 200 that acts as a heatsink may be desirable, in particular, in power semiconductor devices, where considerable power is dissipated in the devices. However, when processing a panel 100 as described in the foregoing, a relatively low yield is obtained for the manufacturing process. In fact, a considerable fraction of devices in a panel are rejected in response to cracks or fractures that form in the semiconductor dice 14 during a grinding step as exemplified in FIG. 1B. In fact, as illustrated in FIG. 1B, the layer of molding material 22 covering the back surface of the semiconductor dice 14 is completely removed, with the grinding/milling apparatus G contacting the back surface of the dice 14 and causing considerable mechanical stress to develop in the semiconductor material of the dice 14. Such issues have been observed to be especially relevant when processing relatively large panels, where a precise control over the grinding/milling apparatus may be difficult to achieve.

Solutions as described herein involve providing a device where heat generated by a semiconductor die in the device may be dissipated via a heat dissipation formation or heatsink.

According to solutions as described herein the heatsink may comprise a thermally conductive layer exposed at a surface of the encapsulation of the device and thermally coupled to the semiconductor die via thermally conductive vias through the encapsulation.

In solutions as described herein, the thermally conductive vias are formed via laser ablation of the encapsulation followed by growth of thermally conductive material.

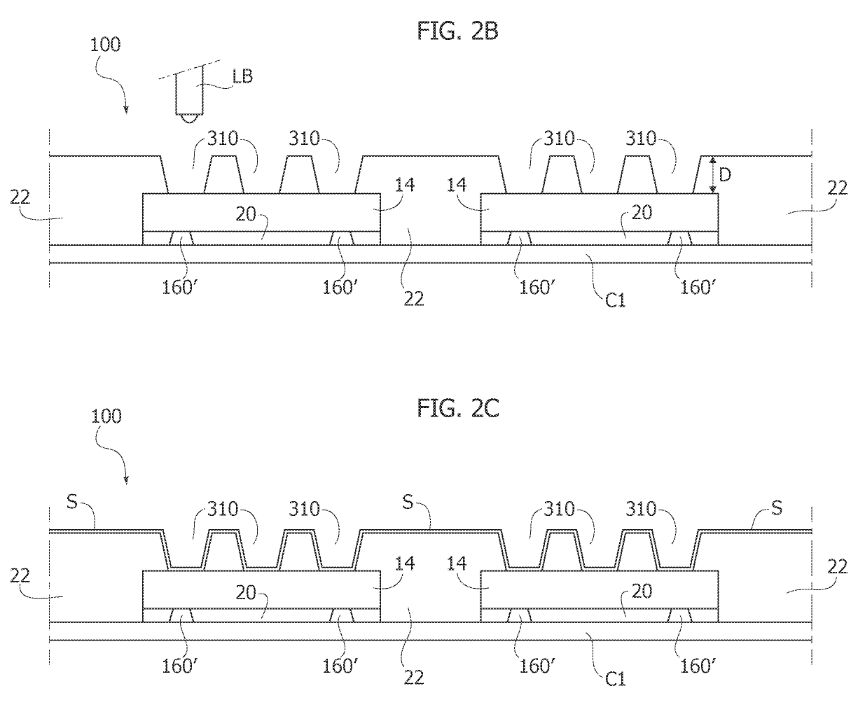

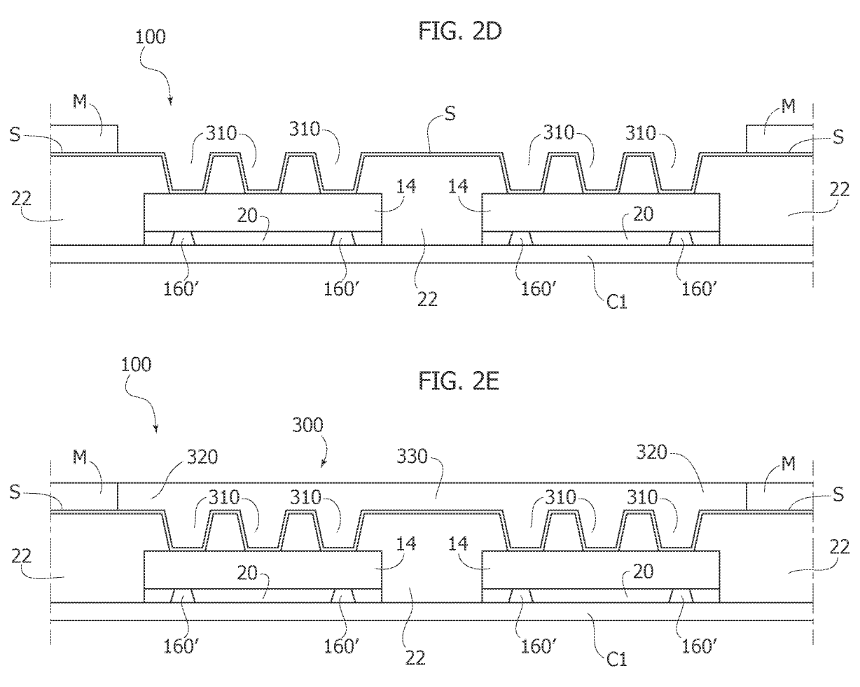

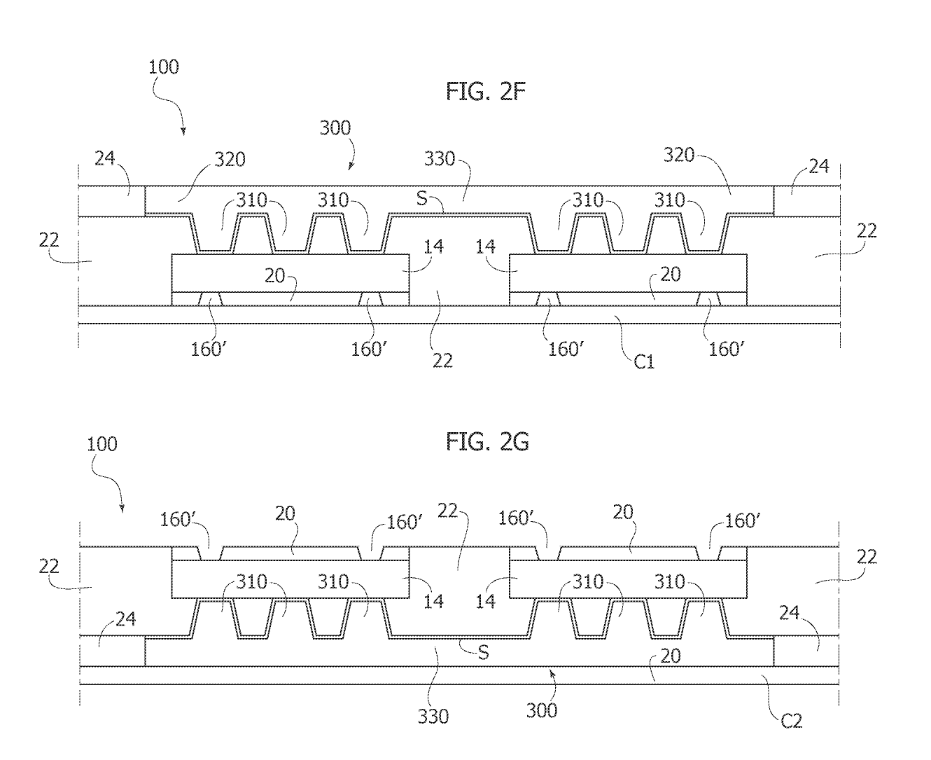

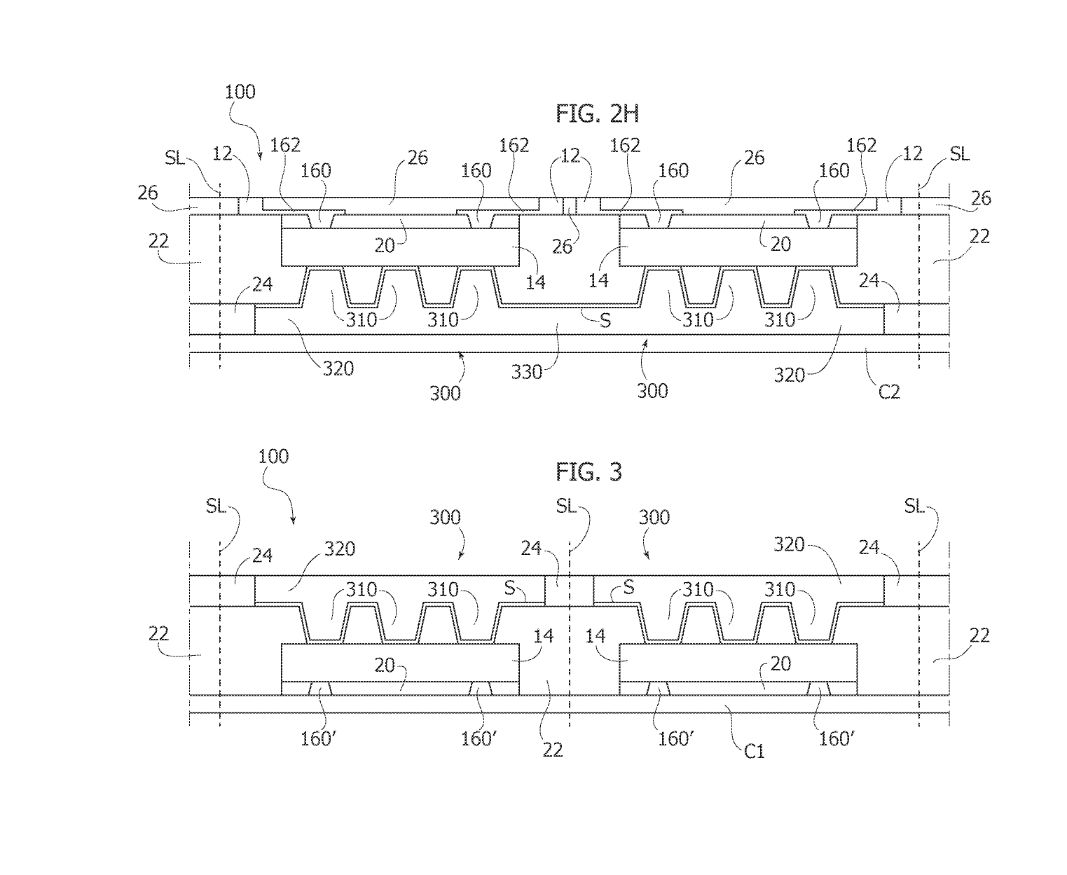

FIGS. 2A -2H are cross-sectional views illustrative of a sequence of processing steps according to embodiments of the present description. In embodiments as exemplified in FIGS. 2A-2H (as well as in FIG. 3), solutions as described herein are applied to so-called panel level manufacturing processes of semiconductor devices, that represent a particularly advantageous, but not mandatory, application of solutions as described herein.

It will be otherwise appreciated that the sequence of steps of FIGS. 2A-2H is merely exemplary insofar as: one or more steps illustrated in FIGS. 2A-2H can be omitted, performed in a different manner (with other tools, for instance) and/or replaced by other steps; additional steps may be added; and one or more steps can be carried out in a sequence different from the sequence illustrated.

FIG. 2A is illustrative of a panel 100 arranged on a first temporary (and possibly sacrificial) carrier C1. Similarly to what has been described previously, the panel 100 comprises a plurality of integrated circuit (IC) semiconductor dice 14 embedded in an electrically insulating molding compound 22 (an epoxy resin, for instance).

As illustrated, the semiconductor dice 14 are arranged with the active surface (that is, the surface having die bonding pads or contacts provided thereon) facing the first carrier C1. As illustrated, the semiconductor dice 14 may have a build-up film 20 laminated onto their active surface, with vias 160’ opened through the build-up film 20 at the die bonding pads (such pads are not visible in the figures for scale reasons).

The back surface of the semiconductor dice 14 (that is, the surface opposite the active surface) is covered with electrically insulating molding compound 22. In fact, the panel 100 may be formed with a layer of molding compound having a layer thickness T (of the order of tens of microns, for instance) over the back surface of the semiconductor dice 14.

Said otherwise, at least one semiconductor die 14 is embedded in an encapsulation 22 of electrically insulating encapsulation material (an epoxy resin, for instance). The encapsulation 22 has first and second opposite surfaces and the at least one semiconductor die 14 is embedded with an active surface thereof at the first surface of the encapsulation 22 and a back surface opposite said active surface covered by electrically insulating encapsulation material 22.

Processing steps to obtain a panel 100 as illustrated in FIG. 2A have been described previously, which makes it unnecessary to provide a more detailed description herein.

FIG. 2B is illustrative of a processing step wherein vias 310 are opened in the molding compound 22 embedding the plurality of semiconductor dice 14. As illustrated in FIG. 2B, vias 310 may be opened by applying laser beam energy LB to selected locations of the second (top) surface of the panel 100 to ablate the molding compound at said selected locations.

Still referring to FIG. 2B, the vias 310 may extend from the second (top) surface of the panel 100 to the back surface of the semiconductor dice 14 in the panel 100, with a via depth D. It is noted that the via depth D and the thickness T of the layer of molding compound over the dice 14 (as illustrated in FIG. 2A, for instance) may be different. That is, the panel 100 may be formed with a layer of molding compound having a first thickness T. A grinding step may follow, in order to reduce the thickness of the molding compound 22 over the dice 14 to a second thickness and, subsequently, vias 310 are formed in the molding compound over the dice 14 with a via depth D notionally equal to the second thickness.

Said otherwise, a grinding step may still be performed in order to reduce the thickness of the panel 100 to a desired value, still leaving a layer of molding compound 22 (having a thickness notionally equal to the via depth D) onto the semiconductor dice 14, covering the back surface thereof. As those skilled in the art may appreciate, in a grinding step where the grinding apparatus does not contact the back surface of the dice 14, a relatively low level of mechanical stress is transferred to the dice 14, resulting in notionally no dice 14 being damaged in response to the grinding step.

In embodiments as illustrated in the figures, three vias 310 are formed in the molding compound 22 covering the back surface of each semiconductor die 14. Of course, a different number of vias 310 or vias 310 having a different shape may be formed as well.

In one or more embodiments, one large via 310 may be formed in the molding compound 22 for each semiconductor die 14 in the plurality of semiconductor dice 14 embedded in the panel 100. That is, at each semiconductor die 14, a sort of cavity (or “large” via 310) is formed (via laser ablation LB) in the molding compound 22 causing a portion of the back surface of the semiconductor die 14 to be exposed (that is, not covered by the molding compound 22). Said otherwise, a set of vias 310 comprising one or more vias 310 may be formed in the second (top) surface of the panel at each semiconductor die 14 in the plurality of semiconductor dice 14.

As illustrated, the vias 310 may extend through the electrically insulating encapsulation 22, from the second (top) surface of the panel 100 to a back surface of the semiconductor dice 14.

FIGS. 2C-2D are illustrative of embodiments of the present description where a heat dissipation formation (or heatsink) is formed at the second (top) surface of the panel 100 by growing thermally conductive material thereon. In the exemplary embodiments illustrated in the figures, the heatsink or heat dissipation formation is formed via electrolytic plating of thermally (and electrically) conductive material (a metallic material such as copper, for instance).

More in detail, as illustrated in FIG. 2C, a seed layer S (a Ti/Cu seed layer, for instance) may be formed at the second (top) surface of the panel 100 (via sputtering, for instance). As illustrated, the seed layer S may be formed over the whole surface of the panel 100, with a seed layer material provided also at the vias 310 formed in the molding compound 22 and at the regions of the back surface of the dice 14 that are not covered by the molding compound 22.

Subsequently, a layer of photoresist material M (a photoresist dry film, for instance) is provided at the second (top/front) surface of the panel 100 having the seed layer S formed thereon. A desired pattern is transferred to the photoresist layer M; this may be done via per se conventional processing steps such as laser direct imaging (LDI) wherein laser beam energy is applied to selected regions of the photoresist layer M, followed by a developing step. This results in a patterned photoresist layer M having apertures at selected regions of the top/front surface of the panel.

As illustrated in FIG. 2D, the patterned photoresist layer M may have apertures formed at each semiconductor die 14 in the plurality of semiconductor dice 14 embedded in the panel 100. In embodiments as illustrated in FIG. 2D, the patterned photoresist layer M has apertures at regions of the second (top) surface of the panel between two adjacent dice 14.

Subsequently, a thermally conductive material such as copper, for instance, may be grown at the top/front surface of the panel 100 via electrolytic plating, facilitated by the seed layer S previously formed.

As known to those skilled in the art, in electrolytic plating (also referred to as galvanic plating or electroplating), an electric field between an anode and a workpiece, acting as a cathode, forces positively charged metal ions (of copper, for instance) to move to the cathode where they give up their charge and deposit as metal on the surface of the workpiece. The seed layer S, which covers the whole second (front/top) surface of the panel 100, acts as a cathode in the electrolytic plating bath, thus facilitating growing metallic material at the selected portions of the seed layer S that are not covered by the patterned photoresist layer M.

FIG. 2E is illustrative of a panel 100 resulting from an electrolytic plating step as described in the foregoing. As illustrated, a heat dissipation formation (or heatsink) 300 is formed at the second surface of the panel 100.

The heat dissipation formation 300 comprises: thermally conductive vias 310, and a thermally conductive layer 320 grown onto the second (top) surface of the panel 100, thermally coupled to (that is, in heat transfer relationship with) the semiconductor dice 14 via the thermally conductive vias 310.

In embodiments as illustrated in FIG. 2E, the heat dissipation formation 300 comprises thermally conductive material 330 grown between two portions of the thermally conductive layer 320 formed over the dice 14. While being optional, growing the further thermally conductive material 330 may be advantageous in so far as it increases the area of the heat dissipation formation 300 exposed at the surface of the devices thus improving dissipation of heat.

Said otherwise, thermally conductive material may be grown at the second surface of the panel 100 to form a heat dissipation formation 300 (common) for a first and a second semiconductor die 14. The heat dissipation formation 300 comprises a thermally conductive layer 320, 330 at the second surface of the panel 100 thermally coupled to the first and second semiconductor die 14 via thermally conductive material 310 grown at a first and a second set of vias 310 towards the back surface of the first and second semiconductor dice (14), respectively, formed in the second surface of the panel 100.

In a subsequent step, the patterned photoresist layer M and the seed material at regions of the seed layer S beneath the patterned photoresist layer M (that is, the region of the seed layer S that does not have metallic material grown thereon) are removed. A further molding step is performed in order to encapsulate the heat dissipation formation 300, resulting in a panel 100 as illustrated in FIG. 2F.

As illustrated in FIG. 2F, a layer of (further) molding compound 24 is molded onto the second surface of the panel 100 (having the heat dissipation 300 formed thereon). The further molding compound 24 leaves the thermally conductive material of the heat dissipation formation 300 exposed at the second (top/front) surface of the panel 100; this may be achieved via a film-assisted molding step or via a molding step followed by a grinding step.

As those skilled in the art may appreciate, forming thermally conductive vias 310 as described herein induces considerably lower mechanical stress in the dice 14 compared to a grinding/milling step where the grinding apparatus contact the back surface of the dice 14; consequently, the risk of cracks formation in the dice 14 is advantageously reduced resulting in a higher yield of the manufacturing process.

FIGS. 2G and 2H are illustrative of possible further steps in processing the panel 100 illustrated in FIG. 2F.

With reference to FIG. 2G, the panel 100 is first detached from the first carrier C1, flipped (that is, turned over), and arranged on a second carrier C2. As illustrated in FIG. 2G, the panel 100 is arranged with the heat dissipation formation 300 facing the second carrier C2 and the active surface of the semiconductor dice 14 (or the first surface of the panel 100) facing upwards.

With reference to FIG. 2H, further processing of a panel 100 as illustrated in FIG. 2G may comprise: growing metallic material (copper, for instance, grown via electrolytic plating) onto the first surface of the panel 100 (that is, onto the build-up film 20 and the molding compound 22) to form a redistribution layer (RDL) comprising electrically conductive vias 160 through the build-up film 20 and electrically conductive traces 162 extending at the first surface of the panel 100; growing further metallic material (again, copper grown via electroplating, for instance) onto selected locations of the RDL 160, 162 to form pads or studs 12, with the pads or studs 12 electrically coupled to the semiconductor dice 14 via the RDL 160, 162; and molding an electrically insulating molding material 26 (an epoxy resin, for instance) to encapsulate the RDL 160, 162 and the pads 12.

In embodiments as exemplified in FIG. 2H, a single layer RDL is formed; as those skilled in the art may appreciate, a RDL comprising a different number of layers may be provided via similar processing steps as those described in the foregoing.

As illustrated, metallic material of the pads 12 may be left uncovered by the molding material 26; this may involve a grinding step where molding material 26 is partially removed to expose metallic material of the pads 12. In fact, final devices are configured to be mounted on a final substrate (a printed circuit board (PCB), for instance) via the pads 12, possibly facilitated by solder material provided (via plating, for instance) onto the metallic material of the pads 12 not covered by the molding material 26.

It is noted that vias 160 of the RDL are grown onto die bonding pads at the active surface of the semiconductor dice 14 that provide electrical contact points for the integrated circuit embedded in the semiconductor dice 14. The pads (or studs) 12 are thus electrically coupled to the integrated circuit in the dice 14 (via the traces 162 and the vias 160, or, equivalently, via the RDL). This is in contrast with the vias 310 at the back surface of the dice 14 (and the heat dissipation formation 300 as a whole), that are thermally coupled to the semiconductor dice 14 (with the thermally conductive layer 320 of the heat dissipation formation 300 in heat exchange relationship with a semiconductor die 14 via the vias 310), and electrically decoupled from the integrated circuit in the dice 14.

The panel 100 is thus singulated by sawing/cutting at singulation lines SL, wherein the panel 100 is partitioned into a plurality of panel portions, each providing a (finished) device.

As mentioned previously, embodiments as illustrated in FIG. 2H may be advantageous for devices comprising two (or more) semiconductor dice 14, with the heat dissipation formation 300 comprising two corresponding sets of thermally conductive vias 310 thermally coupling the two semiconductor dice 14 to a thermally conductive layer 320 common for the two semiconductor dice 14 (comprising a “bridging” region 330 between two regions of the thermally conductive layer 320 lying over the dice 14). As illustrated, the panel 100 is configured to be partitioned into panel portions comprising the two (or more) semiconductor dice 14, with the panel portion comprising a heat dissipation formation 300 common for the two (or more) semiconductor dice 14.

FIG. 3 is illustrative of a panel 100 having formed at a second surface thereof, a heat dissipation formation 300 according to further embodiments the present description. As illustrated, the heat dissipation formation 300 comprises separate, coplanar, thermally conductive layers 320 grown at each semiconductor die 14 in the plurality of semiconductor dice 14 embedded in the panel 100 and thermally coupled thereto via a corresponding set of thermally conductive vias 310.

A panel 100 as illustrated in FIG. 3 may be obtained via processing steps similar to those discussed previously with reference, for instance, to FIGS. 2D-2F, which makes it unnecessary to provide again a detailed description.

The panel 100 exemplified in FIG. 3 may be further processed (providing an RDL for the dice 14, providing pads 12, for instance) and, subsequently, singulated into a plurality of panel portions by cutting or sawing at singulation lines SL. As illustrated, a panel portion may comprise one semiconductor die 14 in heat exchange relationship with a heat dissipation formation 300 comprising a thermally conductive layer 320 thermally coupled to the semiconductor die 14 via a set of thermally conductive vias 310.

In summary, solutions as described herein may involve: embedding at least one semiconductor die 14 in an encapsulation 22 of electrically insulating encapsulation material, wherein the encapsulation 22 has first and second opposite surfaces and the at least one semiconductor die 14 is embedded with an active surface thereof at said first surface of the encapsulation 22 and a back surface opposite said active surface covered by electrically insulating encapsulation material 22; applying laser beam energy LB to the second surface of the encapsulation 22 to form therein vias 310 towards the back surface of the at least one semiconductor die 14; and forming a heat dissipation formation for the at least one semiconductor die 14 by growing thermally conductive material (copper, for instance) at the second surface of encapsulation 22, wherein the heat dissipation formation 300 comprises a thermally conductive layer 320, 330 on the second surface of the encapsulation 22 thermally coupled to (that is, in heat transfer relationship with) the at least one semiconductor die 14 via thermally conductive material 310 grown at said vias 310 formed in the second surface of the encapsulation 22.

In one or more embodiments, the encapsulation 22 has a first and a second semiconductor die 14 embedded therein. Such embodiments may involve: applying laser beam energy LB to the second surface of the encapsulation 22 to form therein first and a second vias 310 towards the back surface of the first and second semiconductor dice 14, respectively; and forming a heat dissipation formation for the first and second semiconductor die 14 by growing thermally conductive material at the second surface of encapsulation 22, wherein the heat dissipation formation 300 comprises a thermally conductive layer 320, 330 on the second surface of the encapsulation 22 thermally coupled to the first and second semiconductor die 14 via thermally conductive material grown at the first and second vias 310 formed in the second surface of the encapsulation 22.

The heat dissipation formation 300 may be encapsulated in a further encapsulation 24 of electrically insulating encapsulation material, wherein the further encapsulation 24 has a surface opposite the second surface of the encapsulation 22, and wherein thermally conductive material of said thermally conductive layer 320, 330 is exposed at the surface of the further encapsulation 24 opposite the second surface of the encapsulation 22.

As discussed, the encapsulation 22 having embedded therein the at least one semiconductor die 14 may be a portion of a panel 100 of electrically insulating encapsulation material comprising a plurality of panel portions, each panel portion having embedded therein at least one semiconductor die 14. Such embodiments may involve: processing the plurality of panel portions via processing steps as described in the foregoing; and singulating the panel 100 into a plurality of singulated panel portions.

Said otherwise, processing a panel 100 may involve: applying laser beam energy LB to the second surface of the panel 100 to form therein sets of vias 310 towards the back surface of respective semiconductor dice; and forming heat dissipation formations 300 for said respective semiconductor dice by growing thermally conductive material at the second surface of panel 100, wherein the heat dissipation formations 300 comprises respective thermally conductive layers 320, 330 on the second surface of the panel 100 thermally coupled to the respective semiconductor dice 14 via thermally conductive material 310 grown at the vias 310 in said sets of vias 310 towards the back surface of respective semiconductor dice formed in the second surface of the panel 100.

A device, obtainable via processing steps as described herein (by singulating a panel processed as described in the foregoing, for instance), may thus comprise: at least one semiconductor die 14 embedded in an encapsulation 22 of electrically insulating encapsulation material, wherein the encapsulation 22 has first and second opposite surfaces and the at least one semiconductor die 14 is embedded with an active surface thereof at said first surface of the encapsulation 22, wherein the second surface of the encapsulation 22 has formed therein vias 310 towards a back surface of the at least one semiconductor die 14 opposite the active surface; and a heat dissipation formation for the at least one semiconductor die 14, wherein the heat dissipation formation 300 comprises a thermally conductive layer 320, 330 at the second surface of the encapsulation 22 thermally coupled to the at least one semiconductor die 14 via thermally conductive material 310 grown at the vias 310 formed in the second surface of the encapsulation 22.

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A method, comprising:
embedding at least one semiconductor die in an encapsulation of electrically insulating encapsulation material, wherein the encapsulation has a first surface and a second surface opposite the first surface, and wherein the at least one semiconductor die is embedded with an active surface thereof at the first surface of the encapsulation and a back surface opposite the active surface covered by electrically insulating encapsulation material;
applying laser beam energy to the second surface of the encapsulation to form therein vias extending from the second surface to the back surface of the at least one semiconductor die; and
forming a heat dissipation formation for the at least one semiconductor die by growing thermally conductive material at the second surface of encapsulation, wherein the heat dissipation formation comprises a thermally conductive layer on the second surface of the encapsulation thermally coupled to the at least one semiconductor die using thermally conductive material grown at the vias formed in the second surface of the encapsulation.

2. The method of claim 1, wherein the encapsulation has a first semiconductor die and a second semiconductor die embedded therein, and the method comprises:
applying laser beam energy to the second surface of the encapsulation to form therein first and second vias towards the back surface of the first semiconductor die and second semiconductor die, respectively; and
forming a heat dissipation formation for the first semiconductor die and second semiconductor die by growing thermally conductive material at the second surface of encapsulation, wherein the heat dissipation formation comprises a thermally conductive layer on the second surface of the encapsulation thermally coupled to the first semiconductor die and second semiconductor die via thermally conductive material grown at the first and second vias formed in the second surface of the encapsulation.

3. The method of claim 1, further comprising encapsulating the heat dissipation formation in a further encapsulation of electrically insulating encapsulation material, wherein the further encapsulation has a surface opposite the second surface of the encapsulation, and wherein thermally conductive material of the thermally conductive layer is exposed at the surface of the further encapsulation opposite the second surface of the encapsulation.

4. The method of claim 1, further comprising growing thermally conductive material at the second surface of the panel to form the heat dissipation formation via electrolytic plating.

5. The method of claim 1, further comprising:
growing, at the first surface of the encapsulation, a redistribution layer for the at least one semiconductor die embedded in the encapsulation; and
growing electrically conductive pads onto the redistribution layer, wherein the electrically conductive pads are electrically coupled to the at least one semiconductor die embedded in the encapsulation via the redistribution layer.

6. The method of claim 1, wherein the encapsulation having embedded therein at least one semiconductor die is a portion of a panel of electrically insulating encapsulation material comprising a plurality of panel portions, each panel portion having embedded therein at least one semiconductor die, and wherein the method further comprises singulating the panel into a plurality of singulated panel portions.

7. A device, comprising:
at least one semiconductor die embedded in an encapsulation of electrically insulating encapsulation material, wherein the encapsulation has a first surface and a second surface opposite the first surface, wherein the at least one semiconductor die is embedded with an active surface thereof at the first surface of the encapsulation, and wherein the second surface of the encapsulation has vias extending from the second surface to a back surface of the at least one semiconductor die opposite the active surface; and
a heat dissipation formation for the at least one semiconductor die comprising thermally conductive material at the second surface of encapsulation, wherein the heat dissipation formation comprises a thermally conductive layer on the second surface of the encapsulation thermally coupled to the at least one semiconductor die via thermally conductive material at the vias in the second surface of the encapsulation.

8. The device of claim 7:
wherein the encapsulation has a first semiconductor die and a second semiconductor die embedded therein, wherein the second surface of the encapsulation has therein a first via and a second via extending towards the back surface of the first semiconductor die and second semiconductor dice, respectively; and
wherein the heat dissipation formation comprises a thermally conductive layer at the second surface of the panel thermally coupled to the first semiconductor die and second semiconductor die via thermally conductive material grown at the first via and second via in the second surface of the encapsulation.

9. The device of claim 7, comprising a further encapsulation of electrically insulating encapsulation material encapsulating the heat dissipation formation, wherein the further encapsulation has a surface opposite the second surface of the encapsulation, and wherein thermally conductive material of the thermally conductive layer is exposed at the surface of the further encapsulation opposite the second surface of the encapsulation.

10. The device of claim 7, comprising:
a redistribution layer for the at least one semiconductor die embedded in the encapsulation grown at the first surface of the encapsulation; and
electrically conductive pads on the redistribution layer, wherein the electrically conductive pads are electrically coupled to the at least one semiconductor die embedded in the encapsulation via the redistribution layer.
